(19) United States
(12) Patent Application Publication
(10) Pub. No.: US 2019/0207052 A1
(43) Pub. Date: Jul. 4, 2019

(54) METHOD OF MANUFACTURING SOLAR CELL, AND SOLAR CELL

(71) Applicant: PANASONIC CORPORATION, Osaka (JP)

(72) Inventors: Keiichiro MASUKO, Osaka (JP); Youhei MURAKAMI, Osaka (JP); Koichi HIRANO, Osaka (JP)

(21) Appl. No.: 16/226,361

(22) Filed: Dec. 19, 2018

(30) Foreign Application Priority Data
Dec. 28, 2017 (JP) 2017-253420

(51) Int. Cl. H01L 31/18; H01L 31/028; H01L 31/0224; H01L 31/06

(52) U.S. Cl. CPC H01L 31/1804; H01L 31/06; H01L 31/022425; H01L 31/028

(57) ABSTRACT

A method of manufacturing a solar cell includes: forming a p-type surface and an n-type surface on the back surface of a photoelectric conversion unit; forming a base layer and a conductive layer above the p-type surface and the n-type surface; forming a resist film on the conductive layer, in a region corresponding to a separating groove; forming an n-side conductive layer and a p-side conductive layer and an n-side tin (Sn) layer and p-side Sn layer which include tin in stated order, by electroplating using, as a seed layer, the conductive layer on which the resist film is formed; forming an n-side metal layer and a p-side metal layer, which are alloyed with the n-side Sn layer and the p-side Sn layer, respectively, on the n-side Sn layer and the p-side Sn layer, respectively; and etching each of the conductive layer and the base layer.

### CROSS REFERENCE TO RELATED APPLICATION

This application claims the benefit of priority of Japanese Patent Application Number 2017-253420 filed on Dec. 28, 2017, the entire content of which is hereby incorporated by reference.

### BACKGROUND

### 1. Technical Field

The present disclosure relates to a method of manufacturing a solar cell, and a solar cell.

### 2. Description of the Related Art

There is disclosed a method of manufacturing a solar battery which includes: a process of forming, on a surface of a semiconductor substrate, a p-type region and an n-type region; a process of forming, on the p-type region and the n-type region, a base layer and a first conductive layer; a process of forming a resist film on the first conductive layer, in a region corresponding to a separating groove; a process of forming, a second conductive layer and an Sn layer in the stated order by electroplating using, as a seed layer, the first conductive layer in which the resist film is formed; a process of forming a surface oxide film by oxidizing a surface of the Sn layer; and a process of etching each of the first conductive layer and the base layer, after removing the resist film (see, for example, Japanese Unexamined Patent Application Publication No. 2015-185658).

With this method of manufacturing a solar battery, it is possible to improve the yield and the economic efficiency in manufacturing a back contact solar battery.

### SUMMARY

However, in conventional methods of manufacturing a solar battery, an etching solution, such as a hydrochloric acid and hydrogen peroxide mixture, is used for etching a base layer, and such etching solution also dissolves an Sn layer formed on a second conductive layer during the etching. For this reason, there is a demand for reducing the dissolving of the Sn layer.

Accordingly, an object of the present disclosure is to provide a method of manufacturing a solar cell that can reduce the dissolving of an Sn layer, and a solar cell.

In order to achieve the above-mentioned object, a method of manufacturing a solar cell according to one aspect of the present disclosure is a method of manufacturing a solar cell in which a p-side electrode and an n-side electrode separated by a separating groove are formed on a surface of a semiconductor substrate. The method includes: forming a p-type region and an n-type region on the surface of the semiconductor substrate; forming a base layer and a first conductive layer above the p-type region and the n-type region; forming a resist film on the first conductive layer, in a region corresponding to the separating groove; forming a second conductive layer and a tin (Sn) layer that includes tin in stated order, by electroplating using, as a seed layer, the first conductive layer on which the resist film is formed; forming a metal layer on the Sn layer, the metal layer being alloyed with a surface of the Sn layer; and etching each of the first conductive layer and the base layer.

In addition, a solar cell according to one aspect of the present disclosure is a solar cell in which a p-side electrode and an n-side electrode separated by a separating groove are formed on a surface of a semiconductor substrate. The solar cell includes: the semiconductor substrate that includes a p-type region and an n-type region on the surface of the semiconductor substrate; a base layer formed on the p-type region and the n-type region; a first conductive layer formed on the base layer; a second conductive layer formed on the first conductive layer; and a tin (Sn) layer covering the second conductive layer. Also, a surface of the Sn layer is alloyed.

According to the present disclosure, the dissolving of the Sn layer can be reduced.

### BRIEF DESCRIPTION OF DRAWINGS

The figures depict one or more implementations in accordance with the present teaching, by way of examples only, not by way of limitations. In the figures, like reference numerals refer to the same or similar elements.

FIG. 1 is a plan view of a solar cell according to an embodiment when seen from a back surface;

FIG. 2 is a cross-sectional view of the solar cell taken along the line II-II in FIG. 1;

FIG. 3 is a flowchart illustrating processes in a method of manufacturing the solar cell according to the embodiment;

FIG. 4 is a cross-sectional view of the solar cell for illustrating the processes in the method of manufacturing the solar cell according to the embodiment;

FIG. 5 is a flowchart illustrating processes in a method of manufacturing a solar cell according to a variation of the embodiment;

FIG. 6A is a cross-sectional view of the solar cell for illustrating the processes in the method of manufacturing the solar cell according to the variation of the embodiment; and

FIG. 6B is a cross-sectional view of the solar cell for illustrating the processes in the method of manufacturing the solar cell according to the variation of the embodiment.

### DETAILED DESCRIPTION OF THE EMBODIMENTS

Hereinafter, embodiments of the present disclosure will be described in detail with reference to the drawings. The embodiments described below each show a particular example of the present disclosure. Therefore, the numerical values, shapes, materials, elements, the arrangement and the connection of the elements, processes, the order of the processes, and the like described in the following embodiments are mere examples, and are not intended to limit the present disclosure. Accordingly, among the elements in the following embodiments, elements not recited in any of the independent claims defining the broadest concept of the present disclosure are described as arbitrary elements.

Note that the drawings are schematic diagrams, and do not necessarily provide strictly accurate illustration. Throughout the drawings, the same reference numeral is given to substantially the same element, and redundant description may be omitted or simplified.

Hereinafter, a solar cell and a method of manufacturing the solar cell according to an embodiment of the present disclosure will be described.

### Embodiment

### [Configuration]

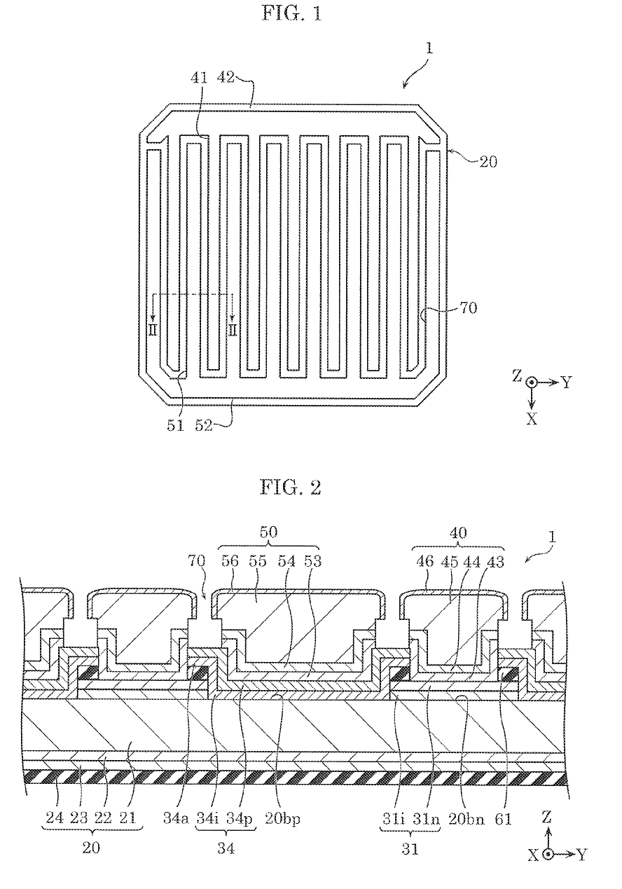

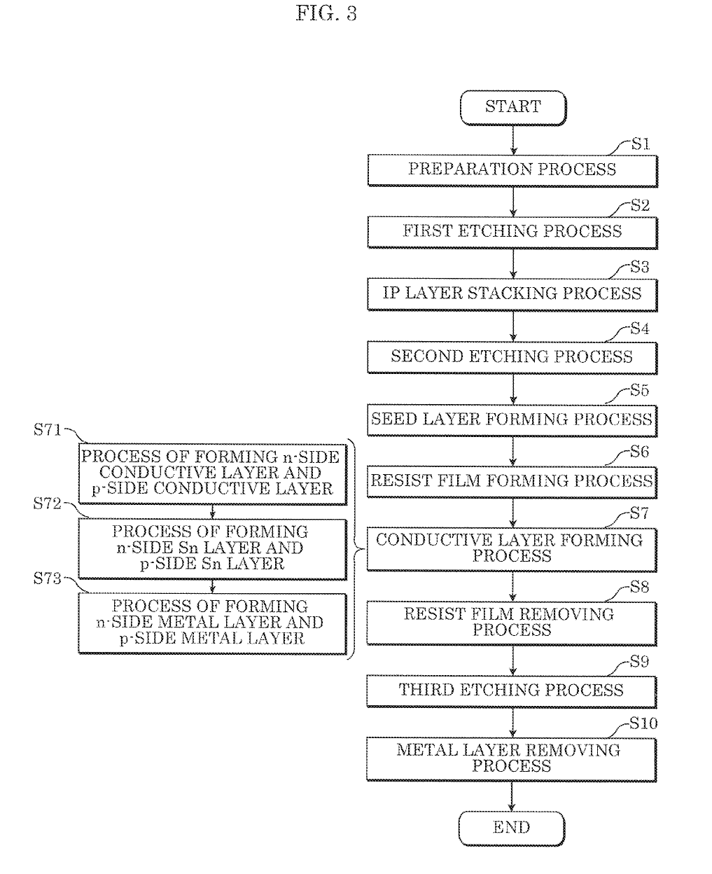

When solar cell 1 is seen in a plan view, directions X, Y, and Z are specified and indicated as follows. The Z-axis direction is a direction normal to solar cell 1, the X-axis direction is an arbitrary direction orthogonal to the Z-axis direction, and the Y-axis direction is a direction orthogonal to the Z-axis direction and the X-axis direction. The directions indicated in FIG. 1 correspond to the directions indicated in FIG. 2. The same applies to all other drawings from FIG. 2 onward, except for the drawings where directions X, Y, and Z are not indicated.

FIG. 1 is a plan view of solar cell 1 according to an embodiment when seen from a back surface.

As illustrated in FIG. 1, solar cell 1 is a light conversion element that can generate electricity by receiving light, such as sunlight. Solar cell 1 includes photoelectric conversion unit 20, n-side electrode 40, and p-side electrode 50.

Photoelectric conversion unit 20 is a component that generates carriers such as electrons and holes by receiving light, such as sunlight. Photoelectric conversion unit 20 may generate carriers when light is received by a light receiving surface of solar cell 1, or may generate carriers when light is received not only by the light receiving surface but also by a back surface of solar cell 1. Here, the “back surface” is a surface of the solar cell on a side opposite to the light receiving surface into which light enters from the outside of a solar battery, and is facing the positive direction of the Z-axis direction. The back surface is an example of a surface.

FIG. 2 is a cross-sectional view of solar cell 1 taken along the line II-II in FIG. 1.

As illustrated in FIG. 1 and FIG. 2, photoelectric conversion unit 20 is provided with p-type surface 20bp and n-type surface 20bn on the back surface of photoelectric conversion unit 20. P-side electrode 50 is provided above p-type surface 20bp. N-side electrode 40 is provided above n-type surface 20bn. N-type surface 20bn is an example of an n-type region. P-type surface 20bp is an example of a p-type region.

P-side electrode 50 and n-side electrode 40 are each provided in the shape of a comb, and are disposed in such a way that p-side electrode 50 and n-side electrode 40 interdigitate with each other. Specifically, p-side electrode 50 includes finger electrode units 51 and bus bar electrode unit 52 to which finger electrode units 51 are electrically connected, and n-side electrode 40 includes finger electrode units 41 and bus bar electrode unit 42 to which finger electrode units 41 are electrically connected. Wiring components not illustrated in the drawings can be connected to each of bus bar electrode unit 42 and bus bar electrode unit 52 to enable modularization into solar battery 10. There is no particular limitation on the elements of the electrodes, such as finger electrode units 41 and finger electrode units 51 and bus bar electrode unit 42 and bus bar electrode unit 52. Accordingly, the electrodes may include only finger electrode units 41 and finger electrode units 51.

In addition, photoelectric conversion unit 20 includes n-type monocrystalline silicon substrate 21 which is a crystalline semiconductor substrate. The crystalline semiconductor substrate may be an n-type polycrystalline silicon substrate, a p-type monocrystalline silicon substrate, or a p-type polycrystalline silicon substrate. In the present embodiment, n-type monocrystalline silicon substrate 21 is used as the crystalline semiconductor substrate. Photoelectric conversion unit 20 is an example of a semiconductor substrate.

N-type monocrystalline silicon substrate 21 functions as a power generation layer. The thickness of n-type monocrystalline silicon substrate 21 is approximately 100 μm to 300 μm, for instance. A texture structure may be formed on a light receiving surface of n-type monocrystalline silicon substrate 21. Here, the “texture structure” is a bumpy structure which decreases surface reflection and increases the amount of light absorption of photoelectric conversion unit 20. A particular example of the texture structure is a structure having quadrangular-pyramid shapes or truncated quadrangular-pyramid shapes which are obtained by anisotropic etching on a light receiving surface having (100) plane.

As illustrated in FIG. 2, i-type amorphous silicon layer 22, n-type amorphous silicon layer 23, and protective layer 24 are formed in the stated order above the light receiving surface of n-type monocrystalline silicon substrate 21. I-type amorphous silicon layer 22 and n-type amorphous silicon layer 23 function as passivation layers.

I-type amorphous silicon layer 22 is a thin film layer made of genuine amorphous silicon, and has a thickness of approximately 0.1 nm to 25 nm, for instance. On the other hand, n-type amorphous silicon layer 23 is a thin film layer made of amorphous silicon doped with phosphorus or the like, and has a thickness of approximately 2 nm to 50 nm, for instance.

Protective layer 24 protects the passivation layers, and has an anti-reflective property. Protective layer 24 may include a material having high light transmittance. Such a material having high light transmittance is, for instance, silicon oxide (SiO₂), silicon nitride (SiN), or silicon oxynitride (SiON). In the present embodiment, an SiN layer is formed as protective layer 24. Although the thickness of protective layer 24 can be suitably changed in consideration of the anti-reflective property or the like, the thickness may be approximately 80 nm to 1 μm, for instance.

In photoelectric conversion unit 20, each of IN amorphous silicon layer 31 (hereinafter, referred to as IN layer 31) which forms n-type surface 20bn and IP amorphous silicon layer 34 (hereinafter, referred to as IP layer 34) which forms p-type surface 20bp are stacked above the back surface of n-type monocrystalline silicon substrate 21. IN layer 31 and IP layer 34 are insulated by insulating layer 61 at an overlapping portion. IN layer 31 and IP layer 34 are directly stacked on the back surface of n-type monocrystalline silicon substrate 21. On the other hand, insulating layer 61 is stacked on portions of IN layer 31.

IN layer 31 includes i-type amorphous silicon layer 31i stacked on the back surface of n-type monocrystalline silicon substrate 21 and n-type amorphous silicon layer 31n stacked on i-type amorphous silicon layer 31i. I-type amorphous silicon layer 31i and n-type amorphous silicon layer 31n can be formed with the same compositions and the same thickness as i-type amorphous silicon layer 22 and n-type amorphous silicon layer 23, respectively.

IP layer 34 is an IP amorphous silicon layer, and includes i-type amorphous silicon layer 34i stacked mainly on the back surface of n-type monocrystalline silicon substrate 21 and p-type amorphous silicon layer 34p stacked on i-type amorphous silicon layer 34i. I-type amorphous silicon layer 34i can be formed with the same composition and the same thickness as, for instance, i-type amorphous silicon layer 22 and i-type amorphous silicon layer 31i. P-type amorphous silicon layer 34p is a thin film layer made of amorphous silicon doped with boron (B) or the like. The thickness of p-type amorphous silicon layer 34p may be approximately 2 nm to 50 nm, for instance.

From the viewpoint of photoelectric conversion efficiency, IN layer 31 and IP layer 34 are alternately formed in a single direction parallel to the back surface of n-type monocrystalline silicon substrate 21. In addition, IN layer 31 and IP layer 34 are formed to cover a wide area of the back surface of n-type monocrystalline silicon substrate 21. For this reason, IN layer 31 and IP layer 34 may be stacked so that a portion of IN layer 31 and a portion of IP layer 34 overlap with each other, with one layer seamlessly overlapping the other, for example. In this case, an insulating layer may be disposed between the one layer and the other layer which is overlapped by the one layer.

Hereinafter, a configuration in which IP layer 34 is stacked so as to overlap IN layer 31 will be exemplified. The portion of IP layer 34 that overlaps IN layer 31 will be described as “overlapping portion 34a”.

Insulating layer 61 is provided at least at a portion between IN layer 31 and IP layer 34 at overlapping portion 34a. Insulating layer 61 has a function of improving insulation between IN layer 31 and IP layer 34. Insulating layer 61 can be formed with the same composition and the same thickness as protective layer 24. Insulating layer 61 is, for instance, an SiN layer that includes SiN.

Insulating layer 61 is formed over the entire region of IN layer 31 on which IP layer 34 is stacked, or in other words, is formed along overlapping portion 34a. Insulating layer 61 is not stacked on a region of IN layer 31 on which IP layer 34 is not stacked.

N-side electrode 40 is an electrode which collects carriers (electrons) from IN layer 31 of photoelectric conversion unit 20. N-side electrode 40 is formed directly on IN layer 31. P-side electrode 50 is an electrode which collects carriers (holes) from IP layer 34 of photoelectric conversion unit 20.

P-side electrode 50 is formed directly on IP layer 34. In the present embodiment, an area of IP layer 34 is larger than an area of IN layer 31. Correspondingly, an area of p-side electrode 50 is larger than an area of n-side electrode 40.

Between n-side electrode 40 and p-side electrode 50, separating groove 70 is formed for separating n-side electrode 40 and p-side electrode 50. Separating groove 70 is spanning across IN layer 31 and IP layer 34. Separating groove 70 is formed on overlapping portion 34a, for instance.

N-side electrode 40 is a stacked body which includes n-side base layer 43 stacked on IN layer 31, n-side seed layer 44 stacked on n-side base layer 43, n-side conductive layer 45 stacked on n-side seed layer 44, and n-side Sn layer 46 stacked on n-side conductive layer 45. P-side electrode 50 is a stacked body which includes p-side base layer 53 stacked on IP layer 34, p-side seed layer 54 stacked on p-side base layer 53, p-side conductive layer 55 stacked on p-side seed layer 54, and p-side Sn layer 56 stacked on p-side conductive layer 55. N-side conductive layer 45 and p-side conductive layer 55 are examples of a second conductive layer.

N-side base layer 43 and p-side base layer 53 are transparent conductive layers (transparent conductive oxide (TCO) films). N-side seed layer 44 and p-side seed layer 54 may include a metal, such as copper (Cu), silver (Ag), or gold (Au). N-side conductive layer 45 and p-side conductive layer 55 may include a metal, such as copper, silver, or gold. In the present embodiment, each of n-side conductive layer 45 and p-side conductive layer 55 includes a Cu layer. N-side Sn layer 46 and p-side Sn layer 56 may include tin. n-side Sn layer 46 and p-side Sn layer 56 are examples of an Sn layer.

The transparent conductive layer has a function of improving reflectance of incident light by preventing contact between photoelectric conversion unit 20 and each of n-side seed layer 44 and p-side seed layer 54, and by preventing alloying of n-side seed layer 44 and p-side seed layer 54 with a semiconductor. The transparent conductive layer may include at least one type of metallic oxides having a polycrystalline structure, such as indium oxide (In₂O₃), zinc oxide (ZnO), tin oxide (SnO₂), or titanium oxide (TiO₂), for instance. In addition, the metallic oxides may be doped with a dopant, such as tin (Sn), zinc (Zn), tungsten (W), antimony (Sb), titanium (Ti), aluminum (Al), cerium (Ce), or gallium (Ga). In the present embodiment, the transparent conductive layer includes indium tin oxide (ITO) obtained by doping In₂O₃ with Sn. The concentration of the dopant can be set to 0 to 20 percent by mass. The thickness of the transparent conductive layer is approximately 50 nm to 100 nm, for instance.

A seed layer, such as n-side seed layer 44 and p-side seed layer 54, includes metal having high conductivity and high light reflectance. In addition, the seed layer may be a layer formable by electroplating. Specifically, a metal, such as copper, tin, titanium, aluminum, nickel (Ni), silver, or gold, or an alloy which includes at least two of the metals can be exemplified as the seed layer.

In the present embodiment, from the viewpoints of, for instance, conductivity, reflectance, and material cost, n-side seed layer 44, p-side seed layer 54, n-side conductive layer 45, and p-side conductive layer 55 are Cu layers. The Cu layers may each have a thickness of approximately 10 μm to 20 μm, for instance. N-side seed layer 44 is formed on the transparent conductive layer, and n-side conductive layer 45 is formed by electroplating using n-side seed layer 44 as a seed layer. In addition, p-side seed layer 54 is formed on the transparent conductive layer, and p-side conductive layer 55 is formed by electroplating using p-side seed layer 54 as a seed layer. Here, “seed layer” refers to a layer through which electricity is allowed to flow during the growth of plating, and n-side conductive layer 45 is formed on n-side seed layer 44 and p-side conductive layer 55 is formed on p-side seed layer 54.

N-side Sn layer 46 is formed on n-side conductive layer 45 and p-side Sn layer 56 is formed on p-side conductive layer 55. For instance, n-side Sn layer 46 has a function of reducing oxidation of n-side conductive layer 45 which is a Cu layer to reduce deterioration of conductivity of n-side conductive layer 45 and p-side Sn layer 56 has a function of reducing oxidization of p-side conductive layer 55 which is a Cu layer to reduce deterioration of conductivity of p-side conductive layer 55. N-side Sn layer 46 and p-side Sn layer 56 may each have a thickness of approximately 1 μm to 5 μm, for instance.

In the present embodiment, when solar cell 1 is manufactured, Cu-containing n-side metal layer 47 and Cu-containing p-side metal layer 57 are formed on n-side Sn layer 46 and p-side Sn layer 56, respectively, or more specifically, on the surfaces of n-side Sn layer 46 and p-side Sn layer 56, respectively, thereby alloying the surfaces of n-side Sn layer 46 and p-side Sn layer 56. When the manufacturing of solar cell 1 is completed, n-side metal layer 47 and p-side metal layer 57 are removed. The metal contained in n-side metal layer 47 and p-side metal layer 57 is not limited to copper. For instance, n-side metal layer 47 and p-side metal layer 57 may be layers which include a metal including nickel, zinc, or the like.

Note that if n-side metal layer 47 and p-side metal layer 57 are formed as thin films on the surfaces of n-side Sn layer 46 and p-side Sn layer 56, respectively, there are cases where n-side metal layer 47 and p-side metal layer 57 need not be removed. In this case, so long as the surfaces of n-side Sn layer 46 and p-side Sn layer 56 are alloyed, the removal of n-side metal layer 47 and p-side metal layer 57 is not essential. N-side metal layer 47 and p-side metal layer 57 are examples of a metal layer.

### [Manufacturing Method]

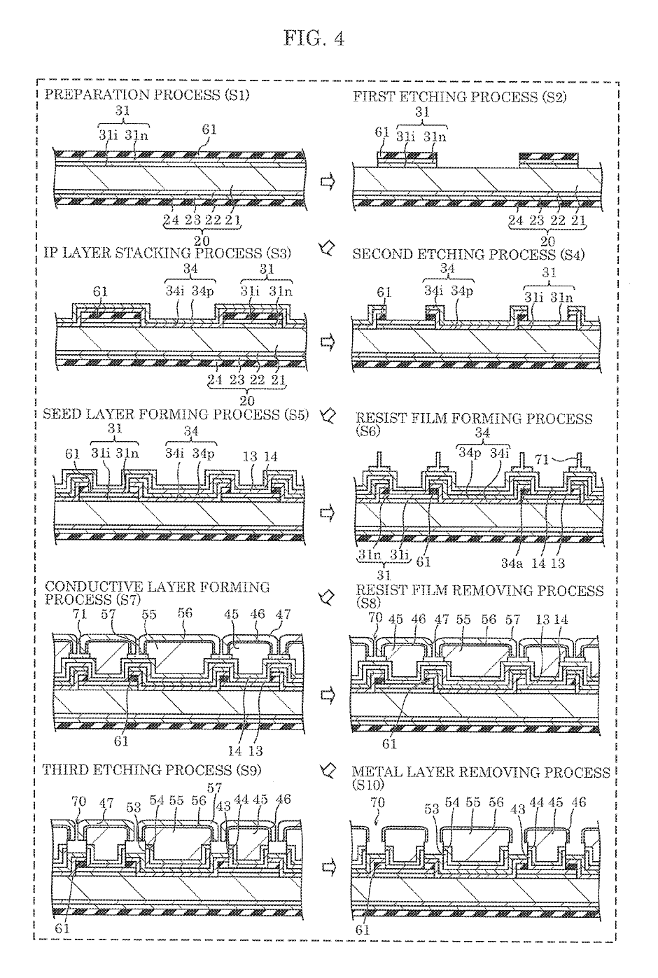

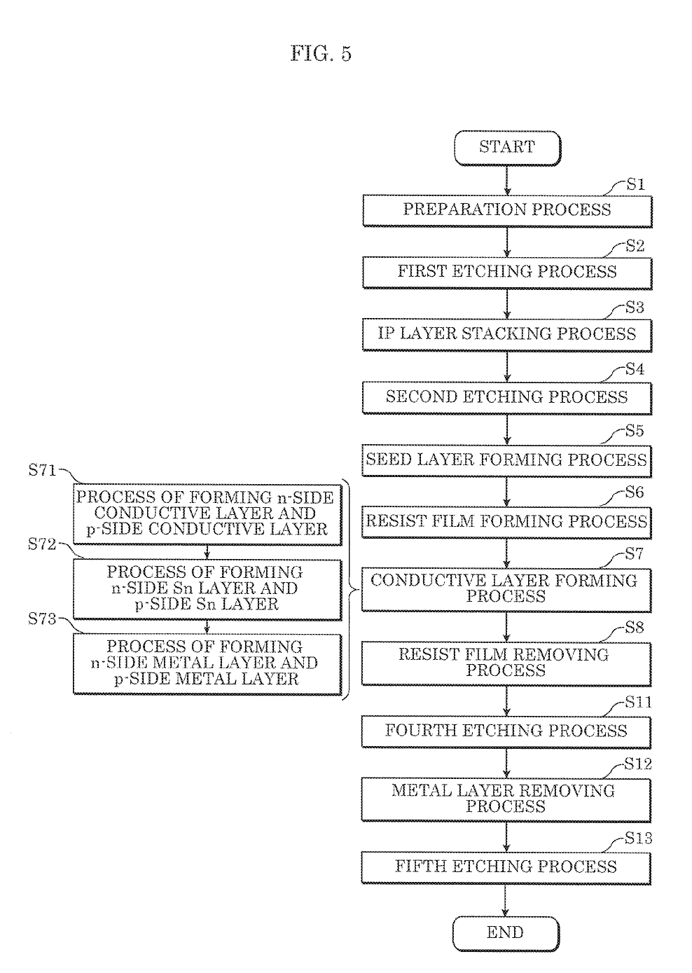

Next, a method of manufacturing solar cell 1 according to the present embodiment will be described with reference to FIG. 3 and FIG. 4.

FIG. 3 is a flowchart illustrating processes in a method of manufacturing solar cell 1 according to the embodiment. FIG. 4 is a cross-sectional view of the solar cell for illustrating of the processes in the method of manufacturing solar cell 1 according to the embodiment.

Firstly, as illustrated in FIG. 3 and FIG. 4, n-type monocrystalline silicon substrate 21 is placed in a vacuum chamber to prepare, by plasma-enhanced chemical vapor deposition (PECVD) and sputtering, a stacked body obtained by stacking i-type amorphous silicon layer, n-type amorphous silicon layer, and insulating layer 61 (protective layer) above n-type monocrystalline silicon substrate 21 in the stated order (S1: preparation process). In the present embodiment, i-type amorphous silicon layer 22, n-type amorphous silicon layer 23, and protective layer 24 are stacked above light receiving surface 11 of n-type monocrystalline silicon substrate 21 in the stated order, and i-type amorphous silicon layer 31i, n-type amorphous silicon layer 31n, and insulating layer 61 are stacked on back surface 12 of n-type monocrystalline silicon substrate 21 in the stated order.

In the process of stacking i-type amorphous silicon layer 22 and i-type amorphous silicon layer 31i by PECVD, silane gas (SiH₄) diluted with hydrogen (H₂) is used as source gas, for instance. In addition, in the process of stacking n-type amorphous silicon layer 23 and n-type amorphous silicon layer 31n, silane gas (SiH₄) to which phosphine (PH₃) is added and which is diluted with hydrogen (H₂) is used as source gas, for instance.

Before i-type amorphous silicon layer 22 and others are stacked above n-type monocrystalline silicon substrate 21, a texture structure may be formed on light receiving surface 11 of n-type monocrystalline silicon substrate 21. The texture structure can be formed by anisotropic etching of the (100) plane using a potassium hydroxide (KOH) aqueous solution, for instance.

Next, each of the layers stacked above back surface 12 of n-type monocrystalline silicon substrate 21 is patterned. Firstly, insulating layer 61 is partially etched and removed (S2: first etching process). In the process of etching insulating layer 61, resist film 71, which is formed by a coating process, such as screen printing or inkjet printing, or photolithography process, for instance, is used as a mask. In the case where insulating layer 61 includes silicon oxide (SiO₂), silicon nitride (SiN), or silicon oxynitride (SiON), insulating layer 61 can be etched using a hydrogen fluoride (HF) aqueous solution, for instance.

After the etching of insulating layer 61 is completed, resist film 71 is removed, and exposed IN layer 31 is also etched using patterned insulating layer 61 as a mask, for instance (S2: first etching process). In an etching process of etching IN layer 31, an alkaline etching solution, such as a sodium hydroxide (NaOH) aqueous solution (for instance, a 1 percent by mass NaOH aqueous solution) is used, for instance. With this process, patterned IN layer 31 and insulating layer 61 are formed above back surface 12.

For the etching of IN layer 31 and insulating layer 61, an etching paste or an etching ink whose viscosity is adjusted may be used, for instance. In this case, the etching paste is applied by, for instance, screen printing or inkjet printing, on regions where IN layer 31 and others have been removed. Note that the same applies to the etching of IP layer 34.

Next, IP layer 34 is stacked on the entirety of back surface 12, except for the edges (S3: IP layer stacking process). Specifically, IP layer 34 is stacked above the patterned IN layer 31 with insulating layer 61 interposed therebetween. Like IN layer 31, IP layer 34 can be formed by forming, i-type amorphous silicon layer 34i and p-type amorphous silicon layer 34p by PECVD in the stated order. However, in the process of stacking p-type amorphous silicon layer 34p, diborane (B₂H₆), for instance, is used as source gas instead of PH₃. The first etching process S2 and the IP layer stacking process S3 are equivalent to processes of forming p-type surface 20bp and n-type surface 20bn.

Next, IP layer 34 stacked above IN layer 31 is patterned. Firstly, in this process, IP layer 34 stacked above IN layer 31 is partially etched and removed (S4: second etching process). The region of IP layer 34 which is to be removed is the region above IN layer 31 where n-side electrode 40 will be formed in a later process. The second etching process in which IP layer 34 is etched is performed using resist film 71 formed by screen printing or the like as a mask, and using an alkaline etching solution, such as an NaOH aqueous solution. In this process, the region of IP layer 34 and the region of IN layer 31 are formed on n-type monocrystalline silicon substrate 21.

Note that since it is usually more difficult to etch IP layer 34 than IN layer 31, an aqueous solution with a higher concentration than the NaOH aqueous solution used for IN layer 31 (for instance, a 10 percent by mass NaOH aqueous solution) or nitrohydrofluoric acid (aqueous solution of a mixture of HF and nitric acid (HNO₃) (a 30 percent by mass of each, for instance) may be used as an aqueous solution for etching IP layer 34. Moreover, an NaOH aqueous solution which is heated to approximately 70° C. to 90° C. (hot alkali treatment) may be used.

In addition, after the etching of IP layer 34 is completed, resist film 71 is removed, and exposed insulating layer 61 is removed by etching using patterned IP layer 34 as a mask, and using an HF aqueous solution (S4: second etching process). Now, a portion of IN layer 31 is exposed due to the removal of a portion of insulating layer 61.

Next, base layer 13 and conductive layer 14 are formed from the bottom in the stated order above IN layer 31 and IP layer 34 (S5: seed layer forming process). Specifically, base layer 13 is stacked on the entirety of IN layer 31 and IP layer 34, and conductive layer 14 is stacked on stacked base layer 13. Base layer 13 subsequently becomes n-side base layer 43 and p-side base layer 53, and conductive layer 14 subsequently becomes n-side seed layer 44 and p-side seed layer 54. Conductive layer 14 includes a Cu layer. Conductive layer 14 is an example of a first conductive layer.

Specifically, in the seed layer forming process, processes are performed in the order of: a process of forming base layer 13 that becomes n-side base layer 43 and p-side base layer 53; a process of forming conductive layer 14 that becomes n-side seed layer 44 and p-side seed layer 54; and a process of forming metal layer 17 that becomes n-side metal layer 47 and p-side metal layer 57. Base layer 13 and conductive layer 14 are formed by means of sputtering. Note that base layer 13 and conductive layer 14 may be formed using other film forming methods, such as PECVD.

Next resist film 71 is formed on conductive layer 14, in a region corresponding to separating groove 70 (S6: resist film forming process). Resist film 71 is formed along a region of conductive layer 14 which corresponds to overlapping portion 34a.

The thickness of resist film 71 is adjusted in accordance with the total thickness of n-side conductive layer 45 and n-side Sn layer 46 which are formed in a later process, and the total thickness of p-side conductive layer 55 and p-side Sn layer 56 which are formed in a later process. For instance, resist film 71 may be formed thicker than the total thickness of n-side conductive layer 45 and n-side Sn layer 46 and the total thickness of p-side conductive layer 55 and p-side Sn layer 56. Specifically, the thickness may be approximately 1 μm to 20 μm. The width of resist film 71 may be made small up to an extent that n-side Sn layer 46 and p-side Sn layer 56 do not come into contact with each other, and may be approximately 10 μm to 200 μm, for instance.

Next, by electroplating using, as a seed layer, conductive layer 14 on which resist film 71 is formed, n-side conductive layer 45 and p-side conductive layer 55, n-side Sn layer 46 and p-side Sn layer 56, and n-side metal layer 47 and p-side metal layer 57 are formed (S7: conductive layer forming process). Specifically, the following three processes are performed by electroplating using conductive layer 14 as the seed layer: a process of forming n-side conductive layer 45 and p-side conductive layer 55 (S71); a process of forming an n-side Sn layer and a p-side Sn layer on n-side conductive layer 45 and p-side conductive layer 55, respectively (S72); and a process of forming n-side metal layer 47 and p-side metal layer 57 on the n-side Sn layer and the p-side Sn layer, respectively (S73). Consequently, an n-side stacked body, which includes n-side conductive layer 45, n-side Sn layer 46, and n-side metal layer 47, and a p-side stacked body, which includes p-side conductive layer 55, p-side Sn layer 56, and p-side metal layer 57, are formed above conductive layer 14. The process of forming n-side conductive layer 45 and p-side conductive layer 55 and the process of forming n-side Sn layer 46 and p-side Sn layer 56 which include tin (Sn), are performed in the stated order, and are equivalent to S71 and S72, respectively.

Here, in the process of forming n-side metal layer 47 and p-side metal layer 57 on the n-side Sn layer and the p-side Sn layer, respectively, surfaces of the n-side Sn layer and the p-side Sn layer are alloyed with n-side metal layer 47 and p-side metal layer 57, respectively. Consequently, the n-side Sn layer and the p-side Sn layer become n-side Sn layer 46 and p-side Sn layer 56, respectively. As such, even if n-side metal layer 47 and p-side metal layer 57 are removed in a subsequent process, the surfaces of n-side Sn layer 46 and p-side Sn layer 56 stay alloyed with copper and tin.

In the case where n-side metal layer 47 and p-side metal layer 57 include nickel, zinc or the like, the surfaces of n-side Sn layer 46 and p-side Sn layer 56 are alloys of, nickel and tin, zinc and tin, or the like.

Since in the plating layers which make up such a stacked body are divisionally formed using resist film 71, the plating layers are separated, and thus it is possible to obtain n-side conductive layer 45 and p-side conductive layer 55, n-side Sn layer 46 and p-side Sn layer 56, and n-side metal layer 47 and p-side metal layer 57. In addition, since conductive layer 14 is not patterned in this process, current density of current which flows during plating processing is constant, thereby making the thickness of n-side conductive layer 45 and n-side Sn layer 46 and the thickness of p-side conductive layer 55 and p-side Sn layer 56 approximately the same.

Since n-side metal layer 47 is stacked on the surface of n-side Sn layer 46 and p-side metal layer 57 is stacked on the surface of p-side Sn layer 56, the surfaces of n-side Sn layer 46 and p-side Sn layer 56 are alloyed. According to the present embodiment, since n-side metal layer 47 and p-side metal layer 57 contain copper, the surfaces of n-side Sn layer 46 and p-side Sn layer 56 become alloys of nickel and tin.

Next, resist film 71 is removed (S8: resist film removing process). Specifically, resist film 71 is removed using alkaline solutions, such as NaOH and KOH. By removing resist film 71, separating groove 70 can be obtained. Here, separating groove 70 is a groove that separates each of n-side conductive layer 45 and p-side conductive layer 55, n-side Sn layer 46 and p-side Sn layer 56, and n-side metal layer 47 and p-side metal layer 57.

Next, using resist film 71 as a mask, conductive layer 14 and base layer 13 which are exposed from separating groove 70 are etched (S9: third etching process). Conductive layer 14 is etched using, for instance, a ferric chloride (FeCl₃) aqueous solution, a hydrochloric acid and hydrogen peroxide mixture, a nitric acid and hydrogen peroxide mixture, a sulfuric acid and hydrogen peroxide mixture, or the like. Base layer 13 is etched using, for instance, a hydrogen chloride (HCl) aqueous solution, an oxalic acid aqueous solution, or the like. Note that the third etching process S9 includes a process of etching conductive layer 14 and a process of etching base layer 13, but these two processes are simplified in the present embodiment.

In the third etching process in which conductive layer 14 and base layer 13 are etched, the surfaces of n-side Sn layer 46 and p-side Sn layer 56 do not dissolve because the surfaces of n-side Sn layer 46 and p-side Sn layer 56 are covered with n-side metal layer 47 and p-side metal layer 57.

Note that in the case where n-side metal layer 47 and p-side metal layer 57 include nickel and a hydrochloric acid and hydrogen peroxide mixture is used for etching base layer 13, n-side metal layer 47 and p-side metal layer 57 can be etched together with base layer 13.

Accordingly, conductive layer 14 is separated at the bottom of separating groove 70, thereby forming n-side seed layer 44 and p-side seed layer 54 which are separated from each other. Base layer 13 is also separated at the bottom of separating groove 70, thereby forming n-side base layer 43 and p-side base layer 53 which are separated from each other.

Next, n-side metal layer 47 and p-side metal layer 57 are removed (S10: metal layer removing process). N-side metal layer 47 and p-side metal layer 57 are etched using, for instance, a ferric chloride (FeCl₃) aqueous solution, a hydrochloric acid and hydrogen peroxide mixture, a nitric acid and hydrogen peroxide mixture, a mixture of sulfuric acid and hydrogen peroxide mixture, ammonium sulfate, or the like. In this manner, solar cell 1 is obtained.

### [Effect]

Next, the effects of the manufacturing method of solar cell 1 and solar cell 1 according to the present embodiment will be described.

As described above, a method of manufacturing solar cell 1 according to the present embodiment is a method of manufacturing solar cell 1 in which p-side electrode 50 and n-side electrode 40 separated by separating groove 70 are formed on the back surface of photoelectric conversion unit 20. The method of manufacturing solar cell 1 includes: the process of forming p-type surface 20bp and n-type surface 20bn on the back surface of photoelectric conversion unit 20; the process of forming base layer 13 and conductive layer 14 above p-type surface 20bp and n-type surface 20bn; the process of forming resist film 71 on conductive layer 14, in a region corresponding to separating groove 70; the process of forming n-side conductive layer 45 and p-side conductive layer 55 and n-side Sn layer 46 and p-side Sn layer 56 which include tin in stated order, by electroplating using, as a seed layer, conductive layer 14 on which resist film 71 is formed; the process of forming n-side metal layer 47 and p-side metal layer 57, which are alloyed with the surfaces of n-side Sn layer 46 and p-side Sn layer 56, respectively, on n-side Sn layer 46 and p-side Sn layer 56, respectively; and the process of etching each of conductive layer 14 and base layer 13.

Accordingly, with the process of forming n-side metal layer 47 and p-side metal layer 57, which are alloyed with the surfaces of n-side Sn layer 46 and p-side Sn layer 56, respectively, on n-side Sn layer 46 and p-side Sn layer 56, respectively, n-side Sn layer 46 and p-side Sn layer 56 are protected by n-side metal layer 47 and p-side metal layer 57. For this reason, n-side Sn layer 46 and p-side Sn layer 56 are not readily dissolved by the etching solution used during the process of etching conductive layer 14 and base layer 13.

Consequently, in the manufacturing method of solar cell 1, it is possible to reduce the dissolving of n-side Sn layer 46 and p-side Sn layer 56.

Particularly, in the manufacturing method of solar cell 1, by performing the process of forming n-side metal layer 47 and p-side metal layer 57 on n-side Sn layer 46 and p-side Sn layer 56, respectively, it is possible to reduce discoloration of n-side Sn layer 46 and p-side Sn layer 56 due to oxidation and growth of whiskers due to a difference in stress between n-side Sn layer 46 and n-side seed layer 44 and between p-side Sn layer 56 and p-side seed layer 54.

In addition, solar cell 1 according to the present embodiment is solar cell 1 in which p-side electrode 50 and n-side electrode 40 separated by separating groove 70 are formed on the back surface of photoelectric conversion unit 20. Solar cell 1 includes: photoelectric conversion unit 20 that includes p-type surface 20bp and n-type surface 20bn on the back surface of photoelectric conversion unit 20; base layer 13 formed on p-type surface 20bp and n-type surface 20bn; conductive layer 14 formed on base layer 13; n-side conductive layer 45 and p-side conductive layer 55 formed on conductive layer 14; and n-side Sn layer 46 and p-side Sn layer 56 which cover n-side conductive layer 45 and p-side conductive layer 55. Also, the surfaces of n-side Sn layer 46 and p-side Sn layer 56 are alloyed.

Solar cell 1 has the same effects as those described above.

In addition, in the method of manufacturing solar cell 1 according to the present embodiment, the thickness of n-side metal layer 47 and p-side metal layer 57 is greater than the thickness of conductive layer 14.

According to this configuration, since the thickness of n-side metal layer 47 and p-side metal layer 57 is greater than the thickness of conductive layer 14, it is possible to prevent the removal of n-side metal layer 47 and p-side metal layer 57 during the process of etching conductive layer 14 in the third etching process. Consequently, the dissolving of n-side Sn layer 46 and p-side Sn layer 56 can be reduced.

In addition, in the method of manufacturing solar cell 1 according to the present embodiment, conductive layer 14 includes a Cu layer.

According to this configuration, since copper has high reflectivity, copper can reliably reflect light that has entered from the light receiving surface, thereby improving power generation efficiency of solar cell 1. In addition, since copper has excellent conductivity, the power generation efficiency does not readily deteriorate. Furthermore, since copper is inexpensive, the manufacturing cost of solar cell 1 does not readily increase.

In addition, in the method of manufacturing solar cell 1 according to the present embodiment, n-side conductive layer 45 and p-side conductive layer 55 include a Cu layer.

Similarly, according to this configuration, since copper has high reflectivity, copper can reliably reflect light that has entered from the light receiving surface, thereby improving power generation efficiency of solar cell 1. In addition, since copper has excellent conductivity, the power generation efficiency does not readily deteriorate. Furthermore, since copper is inexpensive, the manufacturing cost of solar cell 1 does not readily increase.

### Variation of Embodiment

A method of manufacturing solar cell 1 and solar cell 1 according to a variation of the present embodiment will be described.

Elements included in solar cell 1 according to the present variation are the same as the elements included in solar cell 1 according to the present embodiment. Therefore, the same reference numeral is given to the same element, and detailed description regarding the element will be omitted.

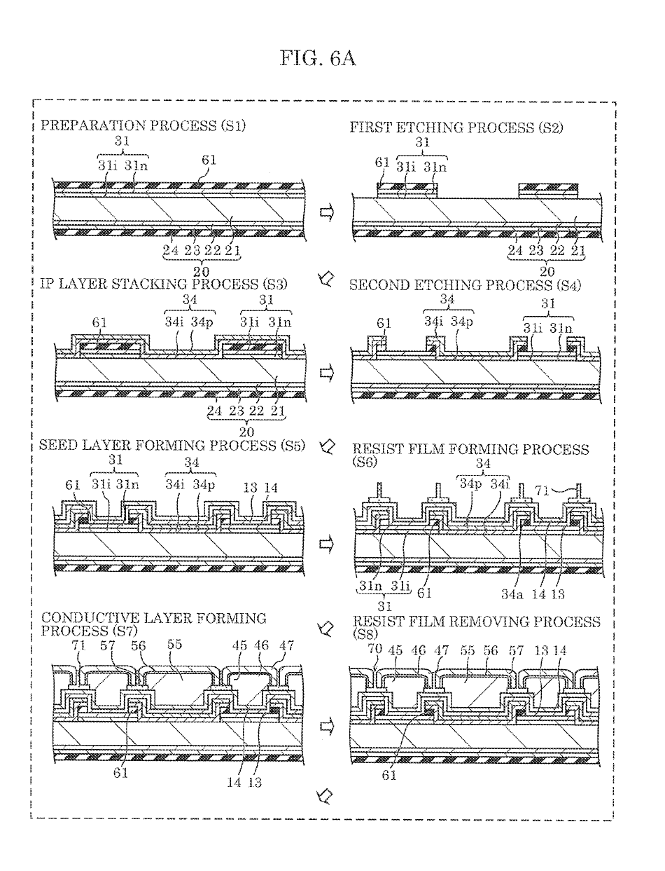

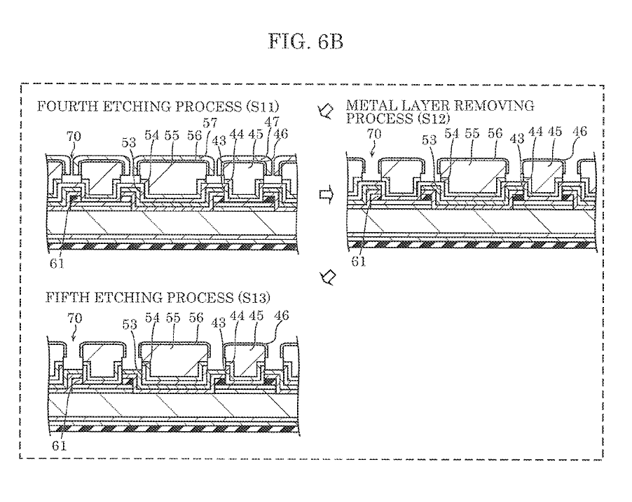

Next, the method of manufacturing solar cell 1 according to the present variation is described with reference to FIG. 5, FIG. 6A, and FIG. 6B.

FIG. 5 is a flowchart illustrating processes in a method of manufacturing solar cell 1 according to a variation of the embodiment. FIG. 6A and FIG. 6B are cross-sectional views of solar cell 1 for illustrating the processes in the method of manufacturing solar cell 1 according to the variation of the embodiment.

As illustrated in FIG. 5 and FIG. 6A, the following processes are performed: the preparation process in step S1; the first etching process in step S2; the IP layer stacking process in step S3; the second etching process in step S4; the seed layer forming process in step S5; the resist film forming process in step S6; the conductive layer forming process in step S7; and the resist film removing process in step S8.

Next, as illustrated in FIG. 5 and FIG. 6B, conductive layer 14, which is exposed from separating groove 70, is etched using resist film 71 as a mask (S11: fourth etching process). Conductive layer 14 is etched using, for instance, a ferric chloride (FeCl₃) aqueous solution, a hydrochloric acid and hydrogen peroxide mixture, a nitric acid and hydrogen peroxide mixture, a sulfuric acid and hydrogen peroxide mixture, or the like.

Next, n-side metal layer 47 and p-side metal layer 57 are removed (S12: metal layer removing process). N-side metal layer 47 and p-side metal layer 57 are etched using, for instance, a ferric chloride (FeCl₃) aqueous solution, a hydrochloric acid and hydrogen peroxide mixture, a nitric acid and hydrogen peroxide mixture, or a sulfuric acid and hydrogen peroxide mixture, or the like. This process of removing n-side metal layer 47 and p-side metal layer 57 from the Sn layer is equivalent to the metal layer removing process S10.

Note that since the same etching solution can be used in steps S11 and S12, these processes can be combined into one process. For this reason, processing can be simplified in this method of manufacturing solar cell 1 according to the present variation.

Next, base layer 13, which is exposed from separating groove 70, is etched using resist film 71 as a mask (S13: fifth etching process). Base layer 13 is etched using a hydrogen chloride (HCl) aqueous solution or an oxalic acid aqueous solution, for instance.

Here, by performing the process of forming n-side metal layer 47 and p-side metal layer 57 on n-side Sn layer 46 and p-side Sn layer 56, respectively in the conductive layer forming process in step S7, the surfaces of n-side Sn layer 46 and p-side Sn layer 56 are alloyed with n-side metal layer 47 and p-side metal layer 57, respectively. For this reason, n-side Sn layer 46 and p-side Sn layer 56 are not readily dissolved by an etching solution, even if n-side metal layer 47 and p-side metal layer 57 are removed before base layer 13 is etched by an etching solution, for instance, a ferric chloride (FeCl₃) aqueous solution, a hydrochloric acid and hydrogen peroxide mixture, a nitric acid and hydrogen peroxide mixture, or a sulfuric acid and hydrogen peroxide mixture.

Accordingly, conductive layer 14 is separated at the bottom of separating groove 70, thereby forming n-side seed layer 44 and p-side seed layer 54 which are separated from each other. Base layer 13 is also separated, thereby forming n-side base layer 43 and p-side base layer 53 which are separated from each other. Consequently, solar cell 1 can be obtained.

In this manner, the method of manufacturing solar cell 1 according to the present variation further includes removing n-side metal layer 47 and p-side metal layer 57 from the Sn layers, after the etching of each of conductive layer 14 and base layer 13 is performed.

According to a configuration according to the present variation, even if n-side metal layer 47 and p-side metal layer 57 are removed before conductive layer 14 and base layer 13 are etched, n-side Sn layer 46 and p-side Sn layer 56 are not readily dissolved because the surfaces of n-side Sn layer 46 and p-side Sn layer 56 are alloyed with n-side metal layer 47 and p-side metal layer 56, respectively. Accordingly, manufacturing processes in this method of manufacturing solar cell 1 is highly flexible.

The present variation produces the same effects as the other effects of the present embodiment.

### Other Variations

The foregoing has described the present disclosure based on the present embodiments, yet the present disclosure is not limited to such embodiments. In following descriptions, the same reference numeral is given to the same element appearing in the above-mentioned present embodiment, and description of the same element may be omitted.

In the method of manufacturing solar cell 1 according to the present embodiment, an oxide film may be formed on the surfaces of n-side Sn layer 46 and p-side Sn layer 56. Surface oxidization may be brought about by simply exposing n-side Sn layer 46 and p-side Sn layer 56, but may also be actively brought about in an atmosphere of, for instance, ozone or hydrogen peroxide. This process of oxidizing the surfaces of n-side Sn layer 46 and p-side Sn layer 56 may be performed before or after the resist film removing process. Furthermore, the process of oxidizing the surfaces of n-side Sn layer 46 and p-side Sn layer 56 may be performed, by using an alkaline solution, during the resist film removing process. The thickness of the oxide film is approximately 1 nm to 100 nm, for instance. The oxide film of n-side Sn layer 46 and p-side Sn layer 56 are not readily etched by an etching solution used in the etching of conductive layer 14. For this reason, etching of n-side Sn layer 46 and p-side Sn layer 56 during the etching of conductive layer 14 can be prevented.

In addition, in the present embodiment, n-type surface 20bn and p-type surface 20bp are formed by stacking IN layer 31 and IP layer 34 in a comb pattern on the back surface of n-type monocrystalline silicon substrate 21 such that IN layer 31 and IP layer 34 interdigitates with each other, but each of the regions may be formed by thermally diffusing dopants. For instance, highly doped n-type surface 20bn may be formed by thermally diffusing an n-type dopant on a first region of the back surface, and p-type surface 20bp may be formed by thermally diffusing p-type dopant on a second region of the back surface.

Furthermore, forms obtained by applying various modifications to the present embodiments which may be conceived by a person skilled in the art, and forms achieved by arbitrarily combining elements and functions in the present embodiments, without departing from the scope of the present disclosure, are also included in the present disclosure.

While the foregoing has described one or more embodiments and/or other examples, it is understood that various modifications may be made therein and that the subject matter disclosed herein may be implemented in various forms and examples, and that they may be applied in numerous applications, only some of which have been described herein. It is intended by the following claims to claim any and all modifications and variations that fall within the true scope of the present teachings.

What is claimed is:

1. A method of manufacturing a solar cell in which a p-side electrode and an n-side electrode separated by a separating groove are formed on a surface of a semiconductor substrate, the method comprising:
forming a p-type region and an n-type region on the surface of the semiconductor substrate;
forming a base layer and a first conductive layer above the p-type region and the n-type region;
forming a resist film on the first conductive layer, in a region corresponding to the separating groove;
forming a second conductive layer and a tin (Sn) layer that includes tin in stated order, by electroplating using, as a seed layer, the first conductive layer on which the resist film is formed;
forming a metal layer on the Sn layer, the metal layer being alloyed with a surface of the Sn layer; and
etching each of the first conductive layer and the base layer.

2. The method of manufacturing the solar cell according to claim 1, further comprising:
removing the metal layer from the Sn layer, after etching each of the first conductive layer and the base layer.

3. The method of manufacturing the solar cell according to claim 1, wherein
a thickness of the metal layer is greater than a thickness of the first conductive layer.

4. The method of manufacturing the solar cell according to claim 1, wherein
the first conductive layer includes a copper (Cu) layer.

5. The method of manufacturing the solar cell according to claim 1, wherein
the second conductive layer includes a Cu layer.

6. A solar cell in which a p-side electrode and an n-side electrode separated by a separating groove are formed on a surface of a semiconductor substrate, the solar cell comprising:
the semiconductor substrate that includes a p-type region and an n-type region on the surface of the semiconductor substrate;
a base layer formed on the p-type region and the n-type region;
a first conductive layer formed on the base layer;
a second conductive layer formed on the first conductive layer; and
a tin (Sn) layer covering the second conductive layer, wherein
a surface of the Sn layer is alloyed.
